(19) United States
(12) Patent Application Publication
(10) Pub. No.: US 2011/0314752 A1
(43) Pub. Date: Dec. 29, 2011

(54) ROOF STRUCTURE HAVING AN ARRANGEMENT OF SOLAR PANELS

(75) Inventor: Christian Meier, Zürich (CH)

(73) Assignee: Energiebüro AG, Zürich (CH)

(21) Appl. No.: 13/129,065

(22) PCT Filed: Nov. 13, 2009
(86) PCT No.: PCT/CH2009/000362

§ 371 Date: Sep. 13, 2011

(30) Foreign Application Priority Data
Nov. 14, 2008 (EP) 08019932.6

(51) Int. Cl. E04D 13/18; H01L 31/042

(52) U.S. Cl. 52/173.3; 126/622

(57) ABSTRACT

In a roof structure having an arrangement of solar panels, horizontally running fixing profiles are in each case arranged between adjacent solar panels. Each fixing profile extends underneath the frame of the respective upper solar panel and over the frame of the respective lower solar panel and both the upper and the lower solar panel are fixed to the fixing profile. In this way, a laying in a tile-like sealing manner is ensured by the fixing profiles, and at the same time the fixing profiles are used to install the solar panels.

### TECHNICAL FIELD

The invention relates to a roof structure having an arrangement of solar panels.

Here, the term “solar panels” is understood to mean plate-like components which are capable of converting solar radiation into other usable forms of energy, in particular electricity or heat. In particular, this includes photovoltaic solar modules (i.e. arrangements of photoelectric solar cells) and solar-thermal collectors (i.e. arrangements which convert solar radiation into heat and heat up a pumped, liquid or gaseous medium of a heating circuit).

### BACKGROUND ART

Arrangements of the generic kind are used to firmly anchor solar panels in a defined position on a building.

Preferably, such an arrangement should fulfill further functions on the building, for example it should be laid in a tile-like sealing manner and thus be able to undertake the role of conventional tiles. “Laid in a tile-like sealing manner” is understood to mean an arrangement of components in which water running off at the bottom end of the first component is caught and is channeled onto the top end of the component lying beneath it, the water thus flowing away over the components as with a tiled roof.

Devices of this kind are disclosed, for example, in U.S. Pat. No. 4,336,413 and DE 33 37 658. However, the design according to U.S. Pat. No. 4,336,524 has the disadvantage that the modules must be held in a specially built frame which makes the design more expensive compared with modules held in normal metal frames. On the other hand, in the solution according to DE 33 37 658, the solar modules overlap one another to such an extent that, when the sun shines at an angle, the lower solar modules can be shaded by the respective upper modules.

### DISCLOSURE OF THE INVENTION

Against this background, the object is to provide an arrangement of the kind mentioned in the introduction which gets along with commercially available solar panels, in particular solar modules, with a metal frame and yet enables the modules to be laid without a risk of shading.

This object is achieved by the roof structure according to claim 1. Accordingly, a fixing profile is in each case arranged between adjacent solar panels in the ridge-eaves direction (i.e. in the direction of fall of the roof). In doing so, the fixing profile extends underneath the frame of the respective upper solar panel and over the frame of the respective lower solar panel and both the upper and the lower solar panel are fixed to the fixing profile. In this way, laying in a tile-like sealing manner is ensured in that the water flows from the bottom end of the respective upper solar panel onto the fixing profile and from there onto the top side of the respective lower solar panel, and at the same time the fixing profiles are used to install the solar panels.

Preferably, at least one anchor which is suspended in the fixing profile is screwed to the underside of the frame on the bottom edge of the respective upper solar panel. This allows the rear fixing holes provided on normal module frames to be used, wherein however the modules provided with the anchors can be installed “from the front”, i.e. without the need for access from the underside of the roof.

In another preferred embodiment of the roof structure according to the invention, the upper solar panel is fixed to the fixing profile by means of a retaining device which overlaps or encompasses the eaves-side frame profile of the frame of the upper solar panel and thereby secures it by positive locking against a lifting-off of the fixing profile. Safeguarding against slipping down in the eaves direction can be undertaken by the component of the retaining device which overlaps or encompasses the frame profile and/or by separate components.

With advantage, the retaining device for overlapping or encompassing the frame profile has a clamp made from a profile material or wire, as components of this kind can be manufactured cost-effectively in large quantities.

Preferably, the clamp engages in a horizontal slot of the fixing profile which is open on the eaves side, and is here prevented from escaping on the eaves side, this preferably occurring in that the slot opens out into a depression in the top side of the fixing profile in which a securing element prevents the clamp from escaping from the slot by positive locking. The securing element can be designed separately or also be formed by the clamp.

A method of construction of this kind favors a simple and secure mounting of the retaining device, in particular when the securing element is made of sheet metal or wire and is fixed by snapping into place, latching and/or spring-elastic clamping to the fixing profile, which is preferred.

At the same time, it is further preferred that the securing element has a tab or a lift-out opening by means of which it can be detached once more without damage by pulling the tab or inserting a lever tool into the lift-out opening. With advantage, the securing element is designed so that it also secures the clamp against a movement along the profile direction of the fixing profile by positive locking.

When the clamp and the securing element are designed separately, it is of advantage that these form a cohesive unit even before installation, which preferably occurs by their being clipped to one another. This significantly simplifies the installation.

Preferably, the retaining device has at least one supporting element which is arranged between the top side of the fixing profile and the underside of the eaves-side frame profile of the upper solar panel and serves to secure this solar panel against slipping in the eaves direction. For this purpose, on the one hand, by engaging in, overlapping and/or encompassing profile sections of the fixing profile, the supporting profile is fixed to the fixing profile in the eaves direction by positive locking and moreover also with advantage is fixed in the ridge direction by positive locking, and on the other hand forms a mechanical stop in the eaves direction for the eaves-side frame profile of the upper solar panel.

If, in doing so, the supporting element is fixed to the fixing profile by snapping into place, latching and/or spring-elastic clamping, then this results in advantages in installation.

If the supporting element consists of a profile material, folded sheet material or wire, or if it includes a basic body made from such material, which is preferred, then this results in the advantage that suitable supporting elements can be manufactured cost effectively in large quantities.

Furthermore, it is of advantage when the supporting element is secured against a movement along the profile direction of the fixing profile by positive locking by means of the clamp of the retaining device. By this means, a separation of clamp and associated supporting element can be reliably prevented.

In a further preferred embodiment of the roof structure according to the invention, starting from an eaves-side boundary edge which is formed by a profile section of the fixing profile which overlaps the frame of the lower solar panel, the top side of the fixing profile extends upwards in the ridge direction and without interruption to beyond a ridge-side boundary edge of the underside of an eaves-side frame profile of the upper solar panel. By this means, it can be ensured that any water escaping from the frame profile is channeled onto the lower solar panel and does not find its way onto the roof or sub roof.

The respective lower solar panel is preferably encompassed at its ridge-side end by at least one retaining device which is formed at least partially by the fixing profile. This simplifies installation in that the solar panel can easily be slid into this retaining device from the eaves-side direction.

The structure can be fixed directly on the roof or sub roof. A foot for fixing to this roof or sub roof can be arranged on the fixing profile for this purpose.

### BRIEF DESCRIPTION OF THE DRAWINGS

Further preferred embodiments can be seen from the dependent claims and from the description which now follows based on the figures. Therein show:

FIG. 1 a first embodiment of the roof structure according to the invention having an arrangement of a plurality of solar modules;

FIG. 2 a section through the ends of two adjacent solar modules of the roof structure of FIG. 1 with interposed fixing profile;

FIG. 3 a section as in FIG. 2 through a second embodiment of the roof structure according to the invention having an arrangement of a plurality of solar modules; and

FIG. 4 a plan view on the area of the roof structure shown in section in FIG. 3.

### MODES FOR CARRYING OUT THE INVENTION

Before describing an exemplary embodiment in more detail, the following terms are defined in order to simplify the notation:

“Ridge-side” is understood to mean the direction facing the roof ridge, i.e. the upwards direction along the line of fall of the roof.

“Eaves-side” is understood to mean the direction facing the eaves of the roof, i.e. the downwards direction along the line of fall of the roof.

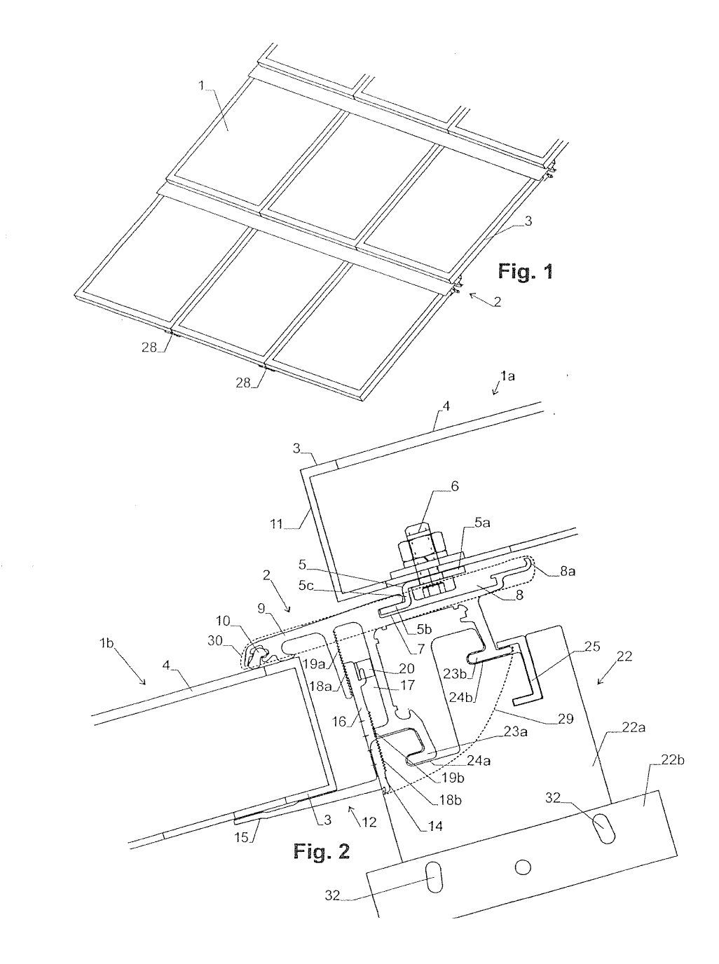

The arrangement shown in FIG. 1 comprises a plurality of solar modules 1 with fixing profiles 2. The structure of the modules and the fixing profile can be seen in detail from FIG. 2.

Each solar module 1 has a frame 3 which is made from a metal profile and extends around the module and holds a front plate 4 made from transparent material. Photovoltaic cells (not shown) are arranged inside the module in the usual manner. The solar modules are commercially available models which do not need to be specially adapted for installation in accordance with the invention.

As can be seen from FIG. 1, the arrangement comprises a plurality of solar modules 1 which are arranged in horizontal rows and in columns along the line of fall of the roof. The fixing profiles 2 run between the horizontal rows in the horizontal direction so that solar modules which lie adjacent to one another in the ridge-eaves direction are in each case connected by a fixing profile 2.

The fixing profile 2 is preferably a profile element made of metal, the cross-section of which remains unchanged over its whole length. It has a length considerably greater than the width of the solar modules so that it extends over a plurality of horizontally adjacent solar modules.

As can be seen from FIG. 1, the solar modules 1 which lie adjacent to one another in the direction of fall of the roof do not overlap, thus extensively enabling the casting of a shadow to be avoided when the sun shines at an angle. The resulting gap between the solar modules is covered by the fixing profile 2.

The embodiment of the fixing profile can be to seen from FIG. 2, which shows the profile between an upper ridge-side module 1a and a lower eaves-side module 1b.

In a ridge-side region, the fixing profile extends beneath the upper solar module 1a and is fixed to its frame 3 from beneath. The top side of the upper solar module 1a is not covered by the fixing profile 2 and is exposed so that water can run off freely.

An anchor, which is formed by a stepped profile 5, is provided for fixing the fixing profile 2 to the upper solar module 1a. The stepped profile 5 has an upper flat section 5a and a lower flat section 5b which are connected by means of a step 5c. The upper section 5a is fixed by means of a screw 6 (or rivet for example) to the frame 3 of the upper solar module 1a. This method of fixing has the advantage that the fixing holes provided in normal solar modules for fixing the modules can be used, enabling a fixing which is compliant with the installation specifications of the module to be achieved.

The bottom end of the anchor or stepped profile 5 engages in a slot 7 of the fixing profile 2 and in this way holds the bottom end of the upper solar module 1a against tension in the direction normal to the roof.

The anchors 5 are significantly shorter in the horizontal direction than the width of the solar modules 1 and have a length of 10 cm for example. As a rule, two separate anchors 5 are provided for each solar module 1; the use of only one anchor 5 is however also basically conceivable. On the other hand, the slot 7 extends over the whole length of the fixing profile 2 so that no special lateral alignment of the solar modules 1 on the battens of the roof is necessary and the solar modules can be placed in any position along the fixing profile 2.

The slot 7 runs horizontally and is open on the ridge side so that the solar modules can be installed in the manner described below. It opens out into a depression 8 on the top side of the fixing profile 2 which creates space for the head of the screw 6 and for sliding the anchor 5 into the slot 7, but at the same time prevents an overflow of water by means of a ridge-side elevation 8a.

An eaves-side arm 9 of the fixing profile 2 rests on the lower solar module 1b from above via an elastic contact-pressure element 10. The arm 9 serves to channel water flowing off the eaves-side edge 11 of the upper solar module 1a onto the top side of the lower solar module 1.

The ridge-side end of the lower solar module 1b is encompassed by a retaining device 12. In the present example, the retaining device 12 is designed in two parts so that it can be adapted to the (non-standardized) thickness of the solar modules. On the one hand, it consists of the already mentioned arm 9 of the fixing profile and the contact-pressure element 10, and on the other hand of a supporting profile 14. The supporting profile 14 has a lower limb 15 which runs approximately parallel to the surface of the roof and supports the lower solar module 1b from beneath. It is held by the fixing profile 2.

The length of the supporting profile 14 in the horizontal direction is preferably substantially less than the width of the solar modules. As a rule, at least two supporting profiles 14 are provided for each solar module; the use of a single supporting profile 14 is however also basically conceivable.

This supporting profile 14 can also be mounted so as to ensure eaves-side connection to conventional roof covering materials. The arrangement can therefore be incorporated into a conventional roof system.

In order to enable the retaining device 12 to be adapted to suit solar modules of different thicknesses, each supporting profile can be fixed to the fixing profile 2 at a plurality of different heights or positions. For this purpose, the supporting profile 14 has a shaft 16 which engages in a recess 17 in the fixing profile 2 which is open on the underside, and is connected by means of at least one, preferably two, toothed surfaces 18a and 18b to correspondingly toothed surfaces 19a, 19b of the fixing profile 2.

In the present embodiment, a first toothed surface 18a of the supporting profile 14 is located on the eaves side at the top end of the shaft 16 and engages in a first ridge-side toothed surface 19a of the fixing profile 2. An elastic clamping element 20, which presses the first toothed surfaces 18a, 19a onto one another and thus improves the holding, is arranged on the side opposite the first toothed surface 18a between the shaft 16 and the fixing profile 2.

Furthermore, in the embodiment shown, a second toothed surface 18b which engages with a corresponding second toothed surface 19b of the fixing profile 2, is also provided on the ridge side on the shaft 16.

Furthermore, a foot in the form of a plate 22 (or also a drawn aluminum profile for example), which for its part is fixed to the roof or sub roof, e.g. to the counter battens, is arranged on the fixing profile 2. For this purpose, the fixing profile 2 has two projections 23a, 23b, which engage in corresponding recesses 24a, 24b of the foot. A securing strap 25, which can be inserted from the side and secures the fixing profile in the foot, is also provided.

The installation of the arrangement is easy and comprises the following steps:

The fixing rails 2 are first fixed to the sub roof or roof by means of the feet or plates 22. The supporting profiles 14 are then fixed to the fixing rails 2 at suitable intervals (e.g. at intervals corresponding to the width of the solar modules 1), namely in each case in such a vertical position that the distance between the limb 15 and the underside of the arm 9 corresponds approximately to the thickness of the solar modules 1.

The anchors 5 are also fixed to the solar modules.

Each solar module can now be installed by first sliding its top edge into one of the retainers 12 where it is held without play by the elastic effect of the contact-pressure element 10. The bottom edge of the solar module is then swiveled down until the lower section 5b comes to rest in the depression 8 of the fixing profile 2. The lower section 5b can then be fed into the slot 7 with a gentle sliding movement of the solar module along the line of fall of the roof, as a result of which the solar module is secured.

In order to prevent water flowing down between two adjacent solar modules through the joints which run in the direction of fall, vertically running profile channels 28 can be arranged underneath these joints as shown in FIG. 1.

In addition, sealing plates, e.g. made of plastic, which prevent water running out of the side of the depression 8, can be fitted to the ends of the fixing profiles. The outline of such a sealing plate is shown with a dashed line 30 in FIG. 2.

In order to prevent the supporting profile 14 falling out before the solar module 1 is installed, this can be pulled against the fixing profile 2 by means of an elastic retaining member 29, e.g. a spring strip, leaf spring or spiral spring, as shown with dashed lines in FIG. 2. Preferably, the retaining member 29 engages with the lower limb 15 and exerts a force thereon which is substantially in the direction of the ridge side.

The arrangement described is suitable for installation on sloping roofs and also on arced roofs. When installing on arced roofs, the angle between the shaft 16 and the limb 15 of the supporting profile can be matched to the respective curvature, or an angle which is other than 90° to the shaft 16 can be imparted to the top side of the limb 15 by inserting plates arranged at an angle or wedge elements. In addition, as shown in FIG. 2, the foot 22 can be designed in two parts, wherein the top part 22a which holds the fixing rail 2 can be tilted with respect to the bottom part 22b which rests on the roof enabling the angle of the fixing rail 2 or the step profile 5 to be matched to the position of the upper solar panel. For example, a connection of the parts 22a, 22b by means of slots 32 can be provided for this purpose as shown in FIG. 2.

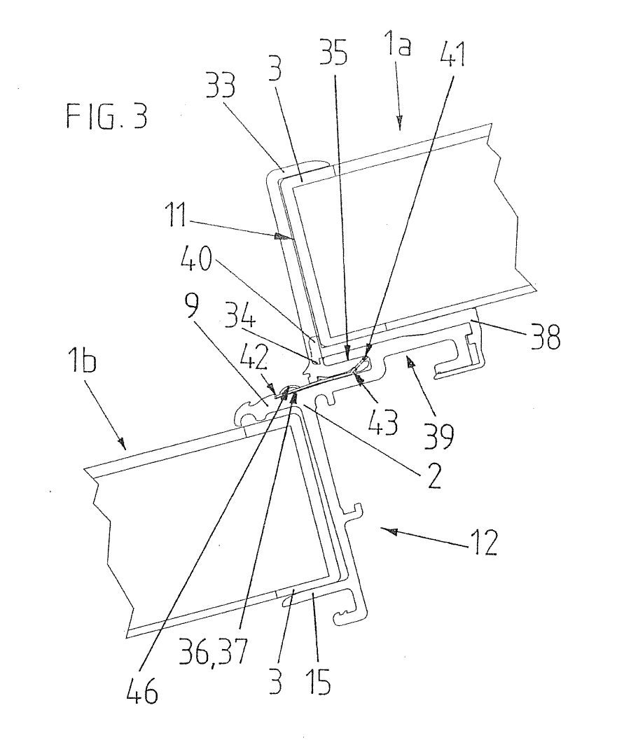

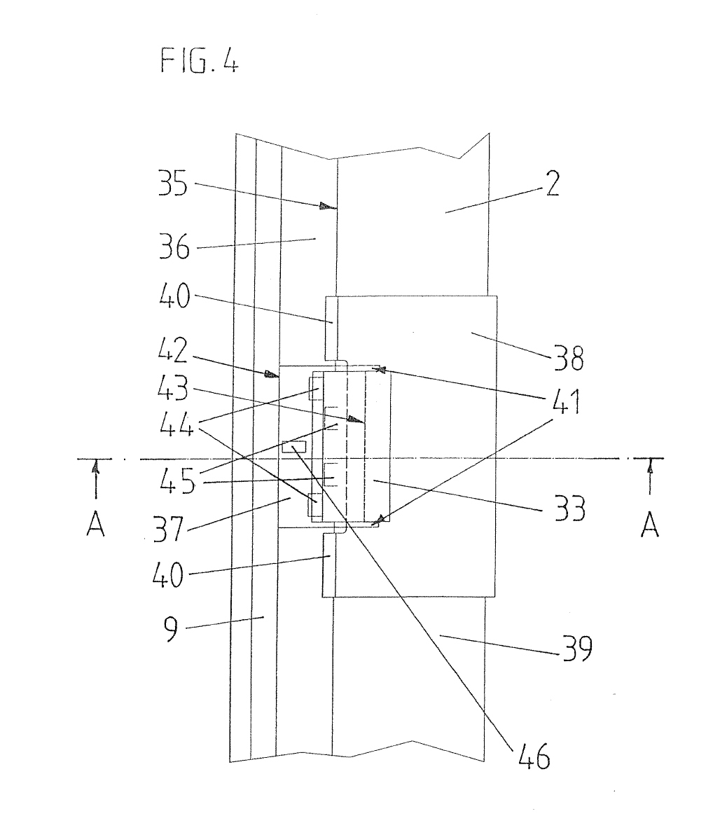

The structure of a second embodiment of the roof structure according to the invention can be seen from FIGS. 3 and 4, wherein FIG. 3 shows a section through the roof structure along the line A-A in FIG. 4 and FIG. 4 shows a plan view on the area of the roof structure shown in section in FIG. 3 but without solar modules.

The structure and the type of arrangement of the solar modules 1a, 1b is identical to that of the embodiment according to FIGS. 1 and 2, on account of which this is not dealt with again here.

As can be seen from FIG. 3, this embodiment has a fixing profile 2 made of aluminum which forms, between a bottom limb 15, which runs substantially parallel to the roof surface and supports the lower solar module 1b from below, and an upper profile arm 9, which overlaps the frame 3 of the lower solar module 1b, a retaining device 12 with a fixed supporting width for the ridge-side end of the lower solar module 1b. As a variation, it is provided that the retaining device 12 is designed as shown in the first exemplary embodiment in FIG. 2 so that it can be adapted to suit solar modules of different thicknesses.

As can also be seen, the upper solar module 1a rests with its frame 3 on a supporting profile piece 38 which in turn rests on the top side of a ridge-side profile section 39 of the fixing profile 2 and encompasses this profile section 39 on the ridge side so that the supporting profile piece 38 is fixed by positive locking to the fixing profile 2 in the eaves direction, i.e. in the direction of fall of the roof. At its eaves-side end, the supporting profile piece 38 forms a mechanical stop 40 on its top side for the eaves-side frame profile of the upper solar module 1a and thus secures said solar module by positive locking against slipping in the eaves direction. On the underside of its eaves-side end, the supporting profile piece 38 has a projection 34 which overlaps the eaves-side boundary edge of the ridge-side profile section 39 of the fixing profile 2 and thus secures the supporting profile piece 38 by positive locking against sliding in the ridge direction. With regard to its material thickness, the section of the supporting profile piece 38 which encompasses the ridge-side profile section 39 of the fixing profile 2 on the ridge side is designed to be significantly thinner in its lower region than the remaining regions of the supporting profile piece 38. This results in the formation of a more elastic region which, during installation, enables the supporting profile piece 38 to be slid from the ridge side onto the ridge-side profile section 39 of the fixing profile 2 until the projection 34 latches behind the eaves-side boundary edge of the ridge-side profile section 39.

As can also be seen, the eaves-side frame profile of the upper solar module 1a is encompassed by a clamp 33 made from an aluminum profile material which engages in a horizontally running slot 35 of the fixing profile 2 which is open on the eaves side and thus secures the eaves-side end of the upper solar module 1a against a lifting-off of the supporting profile piece 38 and therefore against a lifting-off of the fixing profile 2. The slot 35 opens out into a depression 36 in the top side of the fixing profile 2 in which is arranged a securing plate 37 made from stainless spring steel which prevents the clamp 33 from escaping from the slot 35 on the eaves side by positive locking. The securing plate 37 has a tab 46 by means of which it can be removed from the slot 35 once more by pulling up the tab 46 and subsequently removing it on the eaves side together with the clamp 33.

As can be seen, with this second exemplary embodiment of the roof structure according to the invention, the shear forces in the eaves direction, i.e. in the direction of fall of the roof, are transmitted exclusively via the supporting profile piece 38 onto the fixing profile 2. Here, the clamp 33 serves only as a safe-guard against a lifting-off of the solar module 1a.

As can be seen from FIG. 4, which shows a plan view on the fixing situation shown in FIG. 3 without solar modules, the securing plate 37 and the supporting elements 38 encompass the clamp 33 in such a way that a separation of the claimed holding device 33, 37, 38 formed by these components 33, 37, 38 is not possible by sliding the same along the profile direction of the fixing profile 2. In the present case, the clamping of the securing plate 37 in the depression 36 is designed in such a way that, when used as intended, this reliably prevents a movement of the retaining device 33, 37, 38 along the profile direction of the fixing profile 2.

The fixing of the fixing profile 2 on a roof surface, which is not shown here, can be carried out as explained in the first exemplary embodiment and therefore does not have to be explained again at this point.

The installation of a solar module is described briefly below using the above solar module 1a as an example.

When, as already described for the first exemplary embodiment, the fixing rails 2 have been fixed to the roof or sub roof, the supporting profile piece 38 is slid onto the ridge-side profile section 39 of the shown fixing profile 2 from the ridge side until the projection 34 latches behind the eaves-side boundary edge of the so ridge-side profile section 39. Then, the solar module 1a is slid with its upper, i.e. ridge-side, edge into the retaining device 12 of the fixing profile which is arranged above the shown fixing profile 2 in the ridge direction, and subsequently the solar module 1a with its eaves-side frame profile is placed on the supporting profile piece 38 in such a way that it rests in the eaves direction on the two mechanical stops 40 of the supporting profile piece 38.

After that, the clamp 33 and the securing plate 37, which have preferably already been joined together during manufacture to form a cohesive unit by clipping the securing plate 37 to the clamp 33 by means of two lugs 41 which encompass the clamp 33, are slid from the eaves side into the slot 35 of the fixing profile 2 which is open on the eaves side until the securing plate 37 with its eaves-side boundary edge 42 latches in the depression 36 in the top side of the fixing profile 2. In this state, the clamp 33 overlaps the eaves-side frame profile of the solar module 1a and is secured in the slot 35 by positive locking by means of the ridge-side boundary edge 43 of the securing plate 37, the eaves-side boundary edge 42 of which is supported on the eaves-side boundary of the depression 36.

As can be seen in particular from FIG. 4, the securing plate 37 has downward protruding spring tongues 44 and upward protruding spring tongues 45 which are produced by stamping and which serve to hold the securing plate 37 without play in the slot 35 and in the depression 36 and at the same time to press the clamp 33 against the upper boundary of the slot 35.

While preferred embodiments of the invention are described in the present application, it must be clearly pointed out that the invention is not restricted thereto and can also be implemented in other ways within the scope of the claims which now follow. In particular, it is pointed out that the invention is not restricted to the applications for photoelectric applications shown in the exemplary embodiments, but can also be used for the installation of solar-thermal collectors.

1. A roof structure having an arrangement of solar panels laid in a tile-like sealing manner, wherein each solar panel is mounted in a metal frame, characterized in that in each case a fixing profile is arranged between solar panels which lie adjacent to one another in the ridge-eaves direction, wherein the fixing profile extends underneath the frame of the respective upper solar panel and above the frame of the respective lower solar panel, wherein the upper and the lower solar panel are fixed to the fixing profile.

2. The roof structure according to claim 1, wherein the fixing profile is fixed to the upper solar panel from below.

3. The roof structure according to claim 1, wherein at least one anchor which is suspended in the fixing profile to the underside of the frame of the upper solar panel.

4. The roof structure according to claim 3, wherein the anchor engages in a horizontally running slot of the fixing profile which is open on the ridge side.

5. The roof structure according to claim 4, wherein the slot opens out into a depression on the top side of the fixing profile.

6. The roof structure according to claim 3, wherein the anchor is a step profile having an upper and lower flat section, wherein the sections are connected by means of a step, wherein the upper section is retained on the frame of the upper solar panel from below and the lower section engages in the fixing profile.

7. The roof structure according to claim 3, wherein at least one separate anchor is provided for each solar panel.

8. The roof structure according to claim 1, wherein the upper solar panel is fixed to the fixing profile by means of at least one retaining device which overlaps an eaves-side frame profile of the frame of the upper solar panel.

9. The roof structure according to claim 8, wherein the retaining device encompasses the eaves-side frame profile of the upper solar panel.

10. The roof structure according to claim 8, wherein the retaining device comprises a clamp made from a profile material or wire which overlaps or encompasses the eaves-side frame profile of the frame of the upper solar panel.

11. The roof structure according to claim 10, wherein the clamp engages in a horizontally running slot of the fixing profile which is open on the eaves side.

12. The roof structure according to claim 11, wherein the slot opens out into a depression in the top side of the fixing profile in which a securing element, which prevents the clamp from escaping from the slot by positive locking, is arranged.

13. The roof structure according to claim 12, wherein the securing element is made of sheet metal or wire and is fixed by snapping into place, latching and/or spring-elastic clamping to the fixing profile.

14. The roof structure according to claim 13, wherein the securing element has a tab or a lift-out opening by means of which it can be detached once more without damage by pulling the tab or inserting a lever tool into the lift-out opening.

15. The roof structure according to claim 12, wherein the securing element secures the clamp against a movement along the profile direction of the fixing profile by positive locking.

16. The roof structure according to claim 8, wherein the retaining device comprises at least one supporting element which is arranged between the top side of the fixing profile and the underside of the eaves-side frame profile of the frame of the upper solar panel and which by engaging in, overlapping and/or encompassing file sections of the fixing profile is fixed to the fixing profile it by positive locking, and forms a mechanical stop in the eaves direction or the eaves-side frame profile of the upper solar panel in order to secure this solar panel against slipping in the eaves direction.

17. The roof structure according to claim 16, wherein the supporting element consists of a profile material, folded sheet material or wire or includes such material.

18. The roof structure according to claim 17, wherein by engaging in, overlapping and/or encompassing profile sections of the fixing profile, the supporting element is fixed to the fixing profile in the ridge direction by positive locking.

19. The roof structure according to claim 16, wherein the securing element is fixed by snapping into place, latching and/or spring-elastic clamping to the fixing profile.

20. The roof structure according to claim 10, wherein the supporting element is secured by the clamp against a movement along the profile direction of the fixing profile by positive locking.

21. The roof structure according to claim 1, wherein the fixing profile rests on the lower solar panel from above via an elastic contact-pressure element.

22. The roof structure according to claim 1, wherein a ridge-side end of the lower solar panel is encompassed by at least one retaining device, wherein the retaining device is formed at least partially by the fixing profile.

23. The roof structure according to claim 22, wherein the retaining device has a lower limb which supports the lower solar panel from below.

24. The roof structure according to claim 23, wherein the lower limb is formed by a supporting profile which is retained by the fixing profile.

25. The roof structure according to claim 24, wherein the supporting profile can be fixed to the fixing profile in a plurality of positions in order to accommodate solar panels of different thicknesses.

26. The roof structure according to claim 25, wherein a shaft of the supporting profile engages in a recess in the fixing profile and is anchored by means of at least one toothed surface.

27. The roof structure according to claim 24, wherein the supporting profile is pulled against the fixing profile by means of an elastic retaining member.

28. The roof structure according to claim 1, wherein a foot for fixing to a roof or sub roof is arranged on the fixing profile.

29. The roof structure according to claim 1, wherein the upper and lower solar panels do not overlap and a resulting gap between the solar panels is covered by the fixing profile.

30. The roof structure according to claim 29, wherein, starting from an eaves-side boundary edge which is formed by a profile section of the fixing profile which overlaps the frame of the lower solar panel, the top side of the fixing profile extends upwards in the ridge direction and without interruption to beyond a ridge-side boundary edge of the underside of an eaves-side frame profile of the frame of the upper solar panel in order to drain off any water escaping from the frame profile onto the lower solar panel.

31. The roof structure of claim 1 wherein the solar panels are photoelectric solar modules or solar-thermal collectors.

32. The roof structure of claim 3 wherein at least one anchor is screwed or riveted, to the underside of the frame.

33. The roof structure of claim 6 wherein the upper section is retained on the frame of the upper solar panel from below by a screw or rivet.

34. The roof structure of claim 7 wherein at least two separate anchors are provided for each solar panel.

35. The roof structure of claim 20 wherein the supporting element is secured by the clamp against movement along the profile direction due to the fact that it encompasses the clamp.

36. The roof structure of claim 26 wherein the shaft of the supporting profile engages in a recess in the fixing profile and is anchored by means of at least one toothed surface and wherein an elastic clamping element is arranged on aside opposite one of the toothed surfaces between the shaft and the fixing profile.

37. The roof structure of claim 27 wherein retaining member engages with the lower limb and exerts a force thereon which is substantially in the ridge direction.
